(19) United States
(12) Patent Application Publication
(10) Pub. No.: US 2025/0275246 A1
(43) Pub. Date: Aug. 28, 2025

(54) STRETCHABLE DISPLAY DEVICE

(71) Applicant: LG Display Co., Ltd., Seoul (KR)

(72) Inventors: Jun-Hyuk SONG, Paju-si (KR); Sung-Joon MIN, Paju-si (KR); Yeon-Jun OH, Paju-si (KR); Do-Joong KIM, Paju-si (KR); Tae-Hyun KIM, Paju-si (KR)

(21) Appl. No.: 18/918,985

(22) Filed: Oct. 17, 2024

(30) Foreign Application Priority Data
Feb. 28, 2024 (KR) 10-2024-0028515

(51) Int. Cl. H01L 27/12; H01L 25/16

(52) U.S. Cl. CPC H10D 86/60; H01L 25/167; H10D 86/441

(57) ABSTRACT

The present disclosure relates to a stretchable display device. A stretchable display device includes a plurality of rigid portions spaced apart from each other in a first direction and a second direction; a plurality of soft portions each provided between adjacent rigid portions in the first direction or the second direction; a plurality of auxiliary soft portions each provided between adjacent soft portions in the first direction or the second direction; and an auxiliary pattern selectively provided in the plurality of auxiliary soft portions, wherein a height of the auxiliary pattern is equal to or greater than a height of the soft portion and is smaller than or equal to a height of the rigid portion.

### CROSS-REFERENCE TO RELATED APPLICATION

The present application claims priority to Korean Patent Application No. 10-2024-0028515 filed in the Republic of Korea on Feb. 28, 2024, the entire contents of which are hereby expressly incorporated by reference into the present application.

### BACKGROUND

### Technical Field

The present disclosure relates to a display device, and more particularly, to a stretchable display device.

### Description of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

To display an image, the stretchable display device includes a light-emitting element in the rigid portion, and an anisotropic conductive film (ACF) may be used to fix and electrically connect the light-emitting element. The anisotropic conductive film may include an insulating base member and a plurality of conductive balls dispersed in the insulating base member. The anisotropic conductive film may be formed by transferring a transfer film to a plurality of rigid portions at once.

By the way, during the transfer process, an edge of the transfer film may correspond to the rest areas except for the rigid portions, that is, the soft portions, etc. Since the rigid portions are relatively thicker than the soft portions, the edge of the transfer film may sag downward due to the step difference of the rigid portions, resulting in over-transfer of the anisotropic conductive film on the soft portions.

The over-transfer may cause cracks to occur during stretching, lowering the stability of the stretchable display device and causing quality deterioration because the over-transferred anisotropic conductive film is recognized. In addition, due to over-transfer, the anisotropic conductive film may be formed in areas that are not needed, thereby increasing the manufacturing costs.

### BRIEF SUMMARY

Accordingly, the present disclosure is to provide a stretchable display device that substantially obviates one or more of the limitations and disadvantages described above and associated with the background art.

More specifically, an object of the present disclosure is to provide a stretchable display device with relatively high quality and stability.

Another object of the present disclosure is to provide a stretchable display device capable of reducing manufacturing costs.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, a stretchable display device includes a plurality of rigid portions spaced apart from each other in a first direction and a second direction; a plurality of soft portions each provided between adjacent rigid portions in the first direction or the second direction; a plurality of auxiliary soft portions each provided between adjacent soft portions in the first direction or the second direction; and an auxiliary pattern selectively provided in the plurality of auxiliary soft portions, wherein a height of the auxiliary pattern is equal to or greater than a height of the soft portion and is smaller than or equal to a height of the rigid portion.

It is to be understood that both the foregoing general description and the following detailed description are examples and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic plan view of a stretchable display device according to an embodiment of the present disclosure;

FIG. 2 is a plan view schematically enlarging a part of the stretchable display device according to the embodiment of the present disclosure;

FIG. 3 is an equivalent circuit diagram for a sub-pixel of a stretchable display device according to an embodiment of the present disclosure.

FIG. 4 is a schematic cross-sectional view corresponding to line I-I′ of FIG. 2;

FIG. 5 is a schematic cross-sectional view corresponding to line II-II′ of FIG. 2;

FIG. 6 is a schematic plan view of a stretchable display device according to the embodiment of the present disclosure in a transfer step of an adhesive layer;

FIG. 7 is a schematic plan view of a stretchable display device according to the embodiment of the present disclosure in a transfer step of an adhesive layer;

FIG. 8 is a schematic plan view of a stretchable display device according to the embodiment of the present disclosure in a transfer step of an adhesive layer; and

FIG. 9 is a schematic cross-sectional view of a stretchable display device according to another embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiment of the present disclosure will be described in detail with reference to accompanying drawings.

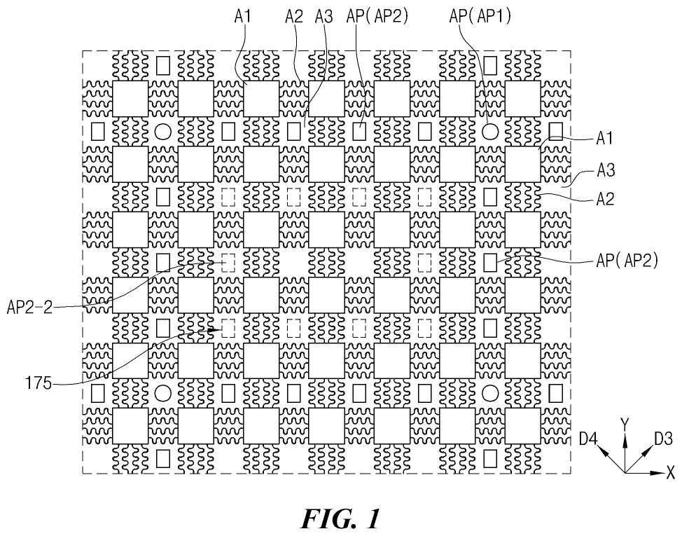

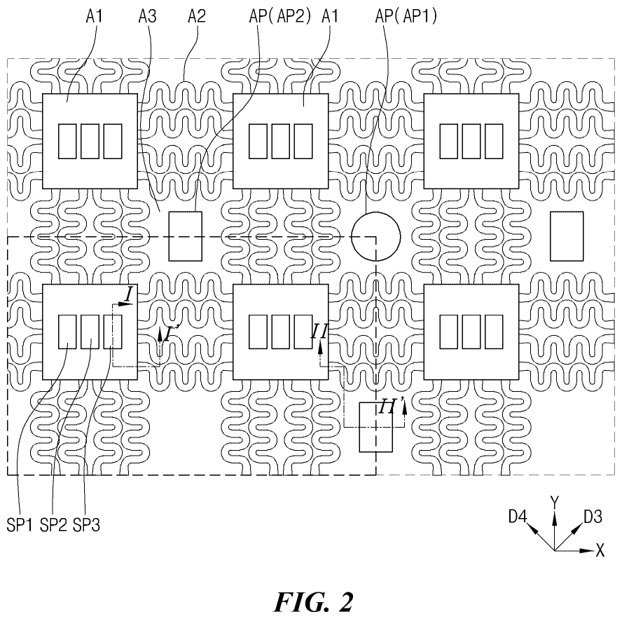

FIG. 1 is a schematic plan view of a stretchable display device according to an embodiment of the present disclosure, and FIG. 2 is a plan view schematically enlarging a part of the stretchable display device according to the embodiment of the present disclosure.

In FIG. 1 and FIG. 2, a stretchable display device according to an embodiment of the present disclosure includes a rigid portion A1 and a soft portion A2 and may be stretched in a first direction X, a second direction Y, or in both the first and second direction. Here, the rigid portion A1 may not be stretched, and the soft portion A2 may be stretched.

The rigid portion A1 may be provided to be plural in the form of an island, and the plurality of rigid portions A1 may be disposed to be spaced apart from each other along the first direction X and the second direction Y. The rigid portions A1 may be disposed in a matrix form.

For example, the rigid portion A1 may have a polygonal shape, and may have a substantially rectangular shape.

A pixel including a plurality of sub-pixels SP1, SP2, and SP3 may be provided in the rigid portion A1. For example, first, second, and third sub-pixels SP1, SP2, and SP3 may be provided in the rigid portion A1, and the first, second, and third sub-pixels SP1, SP2, and SP3 may be red, green, and blue sub-pixels, respectively.

Each of the first, second, and third sub-pixels SP1, SP2, and SP3 may include a light-emitting element, at least one thin film transistor, and at least one capacitor.

The soft portion A2 is disposed between the rigid portions A1 adjacent to each other in the first direction X and the second direction Y. Multiple soft portions A2 may be provided between the adjacent rigid portions A1.

A stretchable line that is a connection line connecting the adjacent pixels may be provided in the soft portion A2. The stretchable line may have at least one curved part. For example, the stretchable line may have a wave structure and may include a plurality of wave shapes.

The stretchable line may include a plurality of signal lines such as a gate line, a data line, a high potential line, a low potential line, an emission line, and a reference voltage line.

In addition, an auxiliary soft portion A3 is provided between adjacent soft portions A2 in the first direction X or the second direction Y. Accordingly, the auxiliary soft portion A3 may be disposed between adjacent rigid portions A1 in a third direction or a fourth direction, such as D3 and D4, crossing the first direction X and the second direction Y. Here, the third direction and the fourth direction cross each other.

Meanwhile, the stretchable display device according to the embodiment of the present disclosure may further include an auxiliary pattern AP. The auxiliary pattern AP is selectively provided in the auxiliary soft portions A3.

Specifically, there are a plurality of the auxiliary soft portions A3, i.e. they may be plural. Some of the plurality of auxiliary soft portions A3 may be provided with the auxiliary patterns AP, and other of the plurality of auxiliary soft portions A3 may be provided without the auxiliary patterns AP. Here, the number of the auxiliary soft portions A3 may be greater than the number of the auxiliary patterns AP.

The auxiliary pattern AP provided in the auxiliary soft portion A3 may be disposed between the adjacent soft portions A2 in the first direction X or the second direction Y. Accordingly, the auxiliary pattern AP may be located between the adjacent rigid portions A1 in the third direction or the fourth direction crossing the first direction X and the second direction Y.

The auxiliary pattern AP may be a plurality of auxiliary patterns in a display area, and the plurality of auxiliary patterns AP may be arranged in the first direction X and the second direction Y to form a substantially rectangular shape.

At this time, the auxiliary patterns AP may be disposed to correspond to a size of a transfer film for an anisotropic conductive film. That is, the rectangle formed by the plurality of auxiliary patterns AP may correspond to the size of the transfer film, and this will be described in detail later.

In addition, the plurality of auxiliary patterns AP may be disposed to extend in the first direction X and the second direction Y from each side of the rectangle. In this case, the plurality of auxiliary patterns AP may substantially form a lattice shape including at least one rectangle.

The number of auxiliary patterns AP may be smaller than the number of rigid portions A1.

Meanwhile, the auxiliary patterns AP may include first patterns AP1 and second patterns AP2. The first patterns AP1 are provided to correspond to corners of the rectangle, that is, the vertexes, and the second patterns AP2 may be provided to correspond to each side of the rectangle. The number of the second patterns AP2 may be greater than the number of the first patterns AP1. See FIG. 1.

Further, as shown in FIG. 1, the first patterns AP1 may be provided to correspond to the corner vertexes of the first rectangle, and each side of the rectangle may be provided to correspond to the second patterns AP2, and additionally, another rectangular shape, which has a smaller size and area than the rectangle formed by the first patterns AP1 and the second patterns AP2 and is formed only by the second patterns AP2, may be further provided adjacent to the rectangle formed by the first patterns AP1 and the second patterns AP2. That is, the second patterns AP2 may be disposed to correspond to the vertexes and the sides of another rectangle. At this time, the another or second rectangle 175 formed by the second patterns AP2-2 may be disposed inside the rectangle formed by the first patterns AP1 and the second patterns AP2.

An area of the first rectangle, which includes the first patterns AP1 and the second patterns AP2 covers a larger area than the second rectangle 175. The second pattern AP2-2 includes a smaller number of second patterns than the first rectangle.

The first pattern AP1 and the second pattern AP2 may have different shapes. For example, the first pattern AP1 may have a circular shape, and the second pattern AP2 may have a rectangular shape. The first pattern AP1 has a first shape and the second pattern AP2 has a second shape. The first shape is different from the second shape in some embodiments.

Here, embodiments of the present disclosure are not limited thereto, and the shapes of the first pattern AP1 and the second pattern AP2 may be changed. For example, the first pattern AP1 may have a cross shape. Additionally, in other embodiments, the first pattern AP1 and the second pattern AP2 may have the same shape.

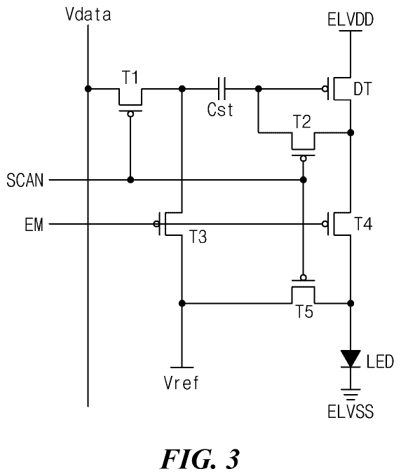

The configuration of the sub-pixel provided in the rigid portion A1 will be described with reference to FIG. 3.

FIG. 3 is an equivalent circuit diagram for a sub-pixel of a stretchable display device according to an embodiment of the present disclosure.

In FIG. 3, one sub-pixel of the stretchable display device according to the embodiment of the present disclosure, that is, each of the first, second, and third sub-pixels SP1, SP2, and SP3 of FIG. 2 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the gate signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the gate signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 3, as an example, each sub-pixel has a 6T1C structure including six transistors and one capacitor, but in other embodiments, each sub-pixel may have one of 2T1C, 4TIC, 5T1C, 3T2C, 4T2C, 5T2C, 6T2C, 7T1C, 7T2C, 8T1C, and 8T2C structures.

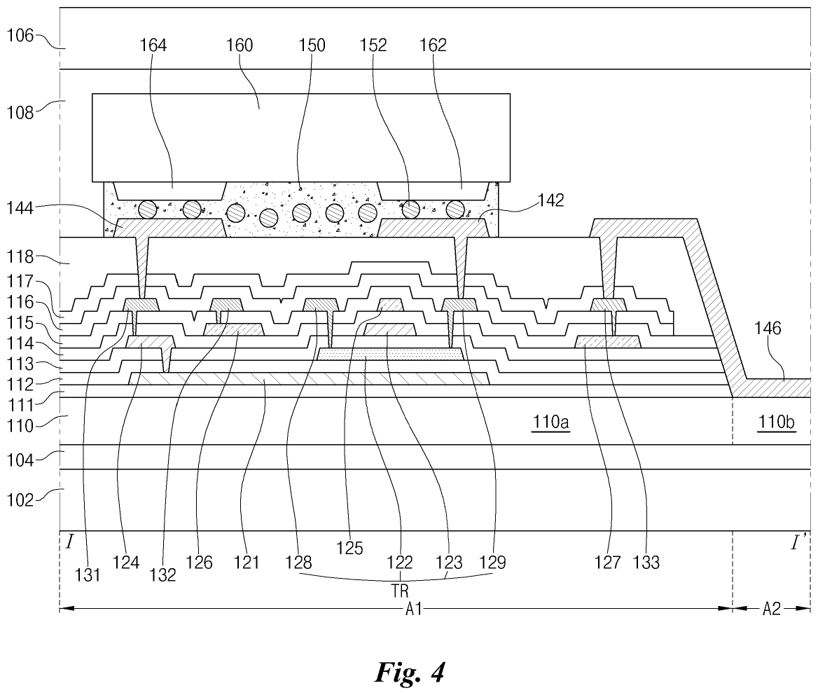

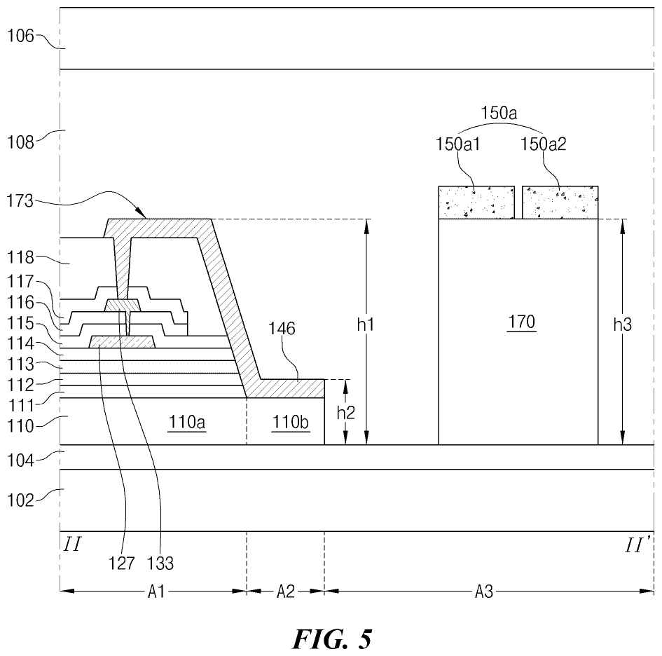

A cross-sectional structure of the stretchable display device according to the embodiment of the present disclosure will be described with reference to FIGS. 4 and 5.

FIG. 4 is a schematic cross-sectional view corresponding to line I-I′ of FIG. 2, and FIG. 5 is a schematic cross-sectional view corresponding to line II-II′ of FIG. 2. FIG. 4 shows a sub-pixel of the stretchable display device according to the embodiment of the present disclosure, and FIG. 5 shows an auxiliary pattern of the stretchable display device according to the embodiment of the present disclosure.

In FIGS. 4 and 5, the stretchable display device according to the embodiment of the present disclosure includes a first substrate 102 and a second substrate 106 facing and spaced apart from each other.

The first substrate 102 and the second substrate 106, which are flexible substrates, may be formed of a soft matter or soft material with bending or stretching properties. For example, the first substrate 102 and the second substrate 106 may be formed of silicone rubber such as polydimethylsiloxane (PDMS), elastomer such as polyurethane (PU), or styrene butadiene block copolymer such as styrene butadiene styrene (SBS).

The first substrate 102 and the second substrate 106 may be formed of the same material. However, embodiments of the present disclosure are not limited thereto. In other embodiments, the first substrate 102 and the second substrate 106 may be formed of different materials.

The first substrate 102 and the second substrate 106 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first substrate 102 and the second substrate 106 may have the elastic modulus of several MPa to hundreds of MPa and the ductile breaking rate of about 100% or more. In addition, each of the first substrate 102 and the second substrate 106 may have a thickness of about 10 μm to about 1 mm, inclusive of 10 μm and 1 mm. However, embodiments of the present disclosure are not limited thereto.

A rigid portion A1 corresponding to a first area, a soft portion A2 corresponding to a second area, and an auxiliary soft portion A3 corresponding to a third area may be provided on the first substrate 102 and the second substrate 106.

A first adhesive layer 104 may be provided on an inner surface of the first substrate 102, and a base substrate 110 may be provided on the first adhesive layer 104.

The first adhesive layer 104 attaches the first substrate 102 and the base substrate 110. The first adhesive layer 104 may be formed of an acryl-based, silicon-based, or urethane-based adhesive. For example, the first adhesive layer 104 may be optically clear adhesive (OCA) that is formed and attached in the form of a film or optically clear resin (OCR) that is cured after applying a liquid material.

The base substrate 110 may include a first base portion 110a and a second base portion 110b. The first base portion 110a may be disposed to correspond to the rigid portion A1, and the second base portion 110b may be disposed to correspond to the soft portion A2. The base substrate 110 may not be provided or can be omitted in the auxiliary soft portion A3. There is an open space at the soft portion A3 in some embodiments. The open space may be surrounded by the second base portion 110b, i.e. spaced from the first based portion 110a by the second base portion 110b.

The first base portion 110a may be provided in a plate shape in the display area and may serve to support and protect components of a plurality of sub-pixels SP1, SP2, and SP3. The first base portion 110a may be plural or there may be multiple base portions 110a, and the plurality of first base portions 110a may be spaced apart from each other in the first direction X and the second direction Y.

The second base portion 110b may be provided between the first base portions 110a adjacent to each other in each of the first direction X and the second direction Y. The second base portion 110b may include at least one curved part and may serve to support and protect a stretchable line 146. The second base portion 110b may have substantially the same shape as the stretchable line 146.

The base substrate 110 may be formed of a rigid material having lower flexibility than the soft material of the first substrate 102. For example, the base substrate 110 may be formed of a polyimide (PI) resin or epoxy resin.

The base substrate 110 may have relatively high elastic modulus, and the elastic modulus of the base substrate 110 may be higher than the elastic modulus of the first substrate 102. For example, the elastic modulus of the base substrate 110 may be more than 1,000 times higher than the elastic modulus of the first substrate 102, but embodiments of the present disclosure are not limited thereto.

Next, a first buffer layer 111 of a first insulation layer may be provided on the base substrate 110. The first buffer layer 111 may block permeation of moisture or oxygen from the outside to protect the components of the plurality of sub-pixels SP1, SP2, and SP3.

The first buffer layer 111 may be formed as a single layer or multiple layers of an inorganic insulating material. The inorganic insulating material of the first buffer layer 111 may include silicon nitride (SiNx), silicon oxide (SiOx), or silicon oxynitride (SiON).

In order to prevent damage of the first buffer layer 111 such as cracks due to stretching, the first buffer layer 111 may be removed in the soft portion A2 to substantially correspond to the rigid portion A1. The first buffer layer 111 may be provided over the first base portion 110a and may not be provided over the second base portion 110b. In addition, the first buffer layer 111 may not be provided over the auxiliary soft portion A3.

Alternatively, in other embodiments, the first buffer layer 111 may be omitted.

A light blocking layer 121 may be provided on the first buffer layer 111 of the rigid portion A1. The light blocking layer 121 may be formed of a conductive material such as metal. For example, the light blocking layer 121 may be formed of at least one of aluminum (Al), copper (Cu), molybdenum (Mo), titanium (Ti), chromium (Cr), nickel (Ni), tungsten (W), or an alloy thereof. The light blocking layer 121 may have a single-layered structure or a multiple-layered structure.

A second buffer layer 112 of a second interlayer insulation layer may be provided on the light blocking layer 121. The second buffer layer 112 may be formed as a single layer or multiple layers of an inorganic insulating material. The inorganic insulating material of the second buffer layer 112 may include silicon nitride (SiNx), silicon oxide (SiOx), or silicon oxynitride (SiON).

In order to prevent damage of the second buffer layer 112 such as cracks due to stretching, the second buffer layer 112 may be removed in the soft portion A2 to substantially correspond to the rigid portion A1. The second buffer layer 112 may be provided over the first base portion 110a and may not be provided over the second base portion 110b. In addition, the second buffer layer 112 may not be provided over the auxiliary soft portion A3.

A semiconductor layer 122 may be provided on the second buffer layer 112. The semiconductor layer 122 may overlap the light blocking layer 121, and the light blocking layer 121 may block light incident on the semiconductor layer 122 and prevent the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 113 of a third insulation layer may be provided on the semiconductor layer 122. The gate insulation layer 113 may be formed as a single layer or multiple layers of an inorganic insulating material. The inorganic insulating material of the gate insulation layer 113 may include silicon nitride (SiNx), silicon oxide (SiOx), or silicon oxynitride (SiON).

In order to prevent damage of the gate insulation layer 113 such as cracks due to stretching, the gate insulation layer 113 may be removed in the soft portion A2 to substantially correspond to the rigid portion A1. The gate insulation layer 113 may be provided over the first base portion 110a and may not be provided over the second base portion 110b. In addition, the gate insulation layer 113 may not be provided over the auxiliary soft portion A3.

A gate electrode 123 and a first connection electrode 124 may be provided on the gate insulation layer 113.

The gate electrode 123 may overlap the semiconductor layer 122 and may be disposed to correspond to the central part of the semiconductor layer 122. Accordingly, the gate electrode 123 may also overlap the light blocking layer 121.

The first connection electrode 124 may be spaced apart from the semiconductor layer 122 and may overlap the light blocking layer 121. The first connection electrode 124 may be in contact with the light blocking layer 121 through a contact hole provided in the second buffer layer 112 and the gate insulation layer 113.

The gate electrode 123 and the first connection electrode 124 may be formed of a conductive material such as metal. For example, the gate electrode 123 and the first connection electrode 124 may be formed of at least one of aluminum (Al), copper (Cu), molybdenum (Mo), titanium (Ti), chromium (Cr), nickel (Ni), tungsten (W), or an alloy thereof. The gate electrode 123 and the first connection electrode 124 may have a single-layered structure or a multiple-layered structure.

A first interlayer insulation layer 114 of a fourth insulation layer may be provided on the gate electrode 123 and the first connection electrode 124. The first interlayer insulation layer 114 may be formed as a single layer or multiple layers of an inorganic insulating material. The inorganic insulating material of the first interlayer insulation layer 114 may include silicon nitride (SiNx), silicon oxide (SiOx), or silicon oxynitride (SiON).

In order to prevent damage of the first interlayer insulation layer 114 such as cracks due to stretching, the first interlayer insulation layer 114 may be removed in the soft portion A2 to substantially correspond to the rigid portion A1. The first interlayer insulation layer 114 may be provided over the first base portion 110a and may not be provided over the second base portion 110b. In addition, the first interlayer insulation layer 114 may not be provided over the auxiliary soft portion A3.

An auxiliary electrode 125, an auxiliary line 126, and a pad electrode 127 may be provided on the first interlayer insulation layer 114. The auxiliary electrode 125 may overlap the gate electrode 123, the semiconductor layer 122, and the light blocking layer 121. The auxiliary line 126 may overlap the light blocking layer 121 and may be spaced apart from the gate electrode 123, the semiconductor layer 122, and the first connection electrode 124. The pad electrode 127 may be spaced apart from the light blocking layer 121 and may be disposed around an edge of the rigid portion A1 adjacent to the soft portion A2.

The auxiliary electrode 125, the auxiliary line 126, and the pad electrode 127 may be formed of a conductive material such as metal. For example, the auxiliary electrode 125, the auxiliary line 126, and the pad electrode 127 may be formed of at least one of aluminum (Al), copper (Cu), molybdenum (Mo), titanium (Ti), chromium (Cr), nickel (Ni), tungsten (W), or an alloy thereof. The auxiliary electrode 125, the auxiliary line 126, and the pad electrode 127 may have a single-layered structure or a multiple-layered structure.

A second interlayer insulation layer 115 of a fifth insulation layer may be provided on the auxiliary electrode 125, the auxiliary line 126, and the pad electrode 127. The second interlayer insulation layer 115 may be formed as a single layer or multiple layers of an inorganic insulating material. The inorganic insulating material of the second interlayer insulation layer 115 may include silicon nitride (SiNx), silicon oxide (SiOx), or silicon oxynitride (SiON).

In order to prevent damage of the second interlayer insulation layer 115 such as cracks due to stretching, the second interlayer insulation layer 115 may be removed in the soft portion A2 to substantially correspond to the rigid portion A1. The second interlayer insulation layer 115 may be provided over the first base portion 110a and may not be provided over the second base portion 110b. In addition, the second interlayer insulation layer 115 may not be provided over the auxiliary soft portion A3.

A source electrode 128, a drain electrode 129, a second connection electrode 131, and a power line 132 may be provided on the second interlayer insulation layer 115.

The source electrode 128 and the drain electrode 129 may be spaced apart from each other with the gate electrode 123 positioned therebetween and may be in contact with both ends of the semiconductor layer 122 through contact holes provided in the first and second interlayer insulation layers 114 and 115 and the gate insulation layer 113. The gate electrode 123 and the auxiliary electrode 125 may be disposed between the source electrode 128 and the drain electrode 129.

The semiconductor layer 122, the gate electrode 123, the source electrode 128, and the drain electrode 129 may constitute a thin film transistor TR.

The second connection electrode 131 may be spaced apart from the thin film transistor TR. The second connection electrode 131 may overlap the first connection electrode 124 and may be in contact with the first connection electrode 124 through a contact hole provided in the first and second interlayer insulation layers 114 and 115. In addition, the second connection electrode 131 may overlap the light blocking layer 121.

The power line 132 may be spaced apart from the thin film transistor TR. The power line 132 may overlap the auxiliary line 126 and may be in contact with the auxiliary line 126 through a contact hole formed in the second interlayer insulation layer 115.

For example, the power line 132 may be a signal line suppling the low potential voltage ELVSS. At this time, the power line 132 or the auxiliary line 126 may be connected to the light blocking layer 121. That is, the light blocking layer 121 may be supplied with the low potential voltage ELVSS.

The source electrode 128, the drain electrode 129, the second connection electrode 131, and the power line 132 may be formed of a conductive material such as metal. For example, the source electrode 128, the drain electrode 129, the second connection electrode 131, and the power line 132 may be formed of at least one of aluminum (Al), copper (Cu), molybdenum (Mo), titanium (Ti), chromium (Cr), nickel (Ni), tungsten (W), or an alloy thereof. The source electrode 128, the drain electrode 129, the second connection electrode 131, and the power line 132 may have a single-layered structure or a multiple-layered structure.

Next, a third interlayer insulation layer 116 of a sixth insulation layer may be provided on the source electrode 128, the drain electrode 129, the second connection electrode 131, and the power line 132. The third interlayer insulation layer 116 may be formed as a single layer or multiple layers of an inorganic insulating material. The inorganic insulating material of the third interlayer insulation layer 116 may include silicon nitride (SiNx), silicon oxide (SiOx), or silicon oxynitride (SiON).

In order to prevent damage of the third interlayer insulation layer 116 such as cracks due to stretching, the third interlayer insulation layer 116 may be removed in the soft portion A2 to substantially correspond to the rigid portion A1. The third interlayer insulation layer 116 may be provided over the first base portion 110a and may not be provided over the second base portion 110b. In addition, the third interlayer insulation layer 116 may not be provided over the auxiliary soft portion A3.

An auxiliary pad 133 may be provided over the third interlayer insulation layer 116. The auxiliary pad 133 may overlap the pad electrode 127 and may be in contact with the pad electrode 127 through a contact hole provided in the second and third interlayer insulation layers 115 and 116.

The auxiliary pad 133 may be formed of a conductive material such as metal. For example, the auxiliary pad 133 may be formed of at least one of aluminum (Al), copper (Cu), molybdenum (Mo), titanium (Ti), chromium (Cr), nickel (Ni), tungsten (W), or an alloy thereof. The auxiliary pad 133 may have a single-layered structure or a multiple-layered structure.

A passivation layer 117 may be provided on the auxiliary pad 133. The passivation layer 117 may be formed as a single layer or multiple layers of an inorganic insulating material. The inorganic insulating material of the passivation layer 117 may include silicon nitride (SiNx), silicon oxide (SiOx), or silicon oxynitride (SiON).

In order to prevent damage of the passivation layer 117 such as cracks due to stretching, the passivation layer 117 may be removed in the soft portion A2 to substantially correspond to the rigid portion A1. The passivation layer 117 may be provided over the first base portion 110a and may not be provided over the second base portion 110b. In addition, the passivation layer 117 may not be provided over the auxiliary soft portion A3.

At this time, edges of the passivation layer 117 and the third interlayer insulation layer 116 of the rigid portion A1 may be partially removed, thereby exposing the top surface of the second interlayer insulation layer 115.

The passivation layer 117 may be omitted.

A planarization layer 118 may be provided on the passivation layer 117. The planarization layer 118 may eliminate a step difference due to the layers thereunder and may have a substantially flat top surface. The planarization layer 118 may be formed of an organic insulating material such as photosensitive acrylic polymer (photo acryl).

The planarization layer 118 may be provided in the rigid portion A1 and may not be provided in the soft portion A2. Accordingly, the planarization layer 118 may be provided over the first base portion 110a and may not be provided over the second base portion 110b.

In the rigid portion A1, the planarization layer 118 may be in contact with side surfaces of the third interlayer insulation layer 116 and the passivation layer 117 and may also be in contact with the exposed top surface of the second interlayer insulation layer 115. In addition, the planarization layer 118 may not be provided in the auxiliary soft portion A3.

A first electrode 142, a second electrode 144, and the stretchable line 146 may be provided on the planarization layer 118. The first electrode 142, the second electrode 144, and the stretchable line 146 may be formed of a conductive material such as metal. For example, the first electrode 142, the second electrode 144, and the stretchable line 146 may be formed of at least one of aluminum (Al), copper (Cu), molybdenum (Mo), titanium (Ti), chromium (Cr), nickel (Ni), tungsten (W), or an alloy thereof. The first electrode 142, the second electrode 144, and the stretchable line 146 may have a single-layered structure or a multiple-layered structure.

The first electrode 142 may overlap the drain electrode 129 and may be in contact with the drain electrode 129 through a contact hole provided in the planarization layer 118, the passivation layer 117, and the third interlayer insulation layer 116. The second electrode 144 may overlap the second connection electrode 131 and may be in contact with the second connection electrode 131 through a contact hole provided in the planarization layer 118, the passivation layer 117, and the third interlayer insulation layer 116.

One end of the stretchable line 146 may be disposed on the planarization layer 118 of the rigid portion A1. The one end of the stretchable line 146 may overlap the auxiliary pad 133 and may be in contact with the auxiliary pad 133 through a contact hole provided in the planarization layer 118 and the passivation layer 117. At this time, the one end of the stretchable line 146 may also overlap the pad electrode 127.

The stretchable line 146 may extend into and be provided in the soft portion A2. The stretchable line 146 may be in contact with top and side surfaces of the planarization layer 118 in the rigid portion A1 and may be in contact with the top surface of the second base portion 110b in the soft portion A2. The stretchable line 146 may also be in contact with the side surfaces of the first buffer layer 111, the second buffer layer 112, the gate insulation layer 113, the first interlayer insulation layer 114, and the second interlayer insulation layer 115.

Meanwhile, although not shown in the figures, a bank layer may be further provided on the first electrode 142, the second electrode 144, and the stretchable line 146 in the rigid portion A1. The bank layer may expose at least parts of the first electrode 142 and the second electrode 144 and may cover the one end of the stretchable line 146.

Next, an adhesive layer 150 may be provided on the first and second electrodes 142 and 144 of the rigid portion A1. The adhesive layer 150 may be an anisotropic conductive film (ACF) including an insulating base member and a plurality of conductive balls 152 dispersed in the insulating base member.

When heat or pressure is applied to the adhesive layer 150, in an area where the heat or pressure is applied, the conductive balls 152 may be electrically connected, so that the adhesive layer 150 may have a conductive property, and in an area where the heat or pressure is not applied, the adhesive layer 150 may have an insulating property.

A light-emitting element 160 may be provided on the adhesive layer 150. The light-emitting element 160 may include a first element electrode 162 and a second element electrode 164.

Here, the first element electrode 162 may be a p-electrode, and the second element electrode 164 may be an n-electrode. The first element electrode 162 may be an anode, and the second element electrode 164 may be a cathode. However, embodiments of the present disclosure are not limited thereto.

Alternatively, in other embodiments, the first element electrode 162 may be an n-electrode, and the second element electrode 164 may be a p-electrode. In this case, the first element electrode 162 may be a cathode, and the second element electrode 164 may be an anode.

The light-emitting element 160 may be provided in the form of a micro light-emitting diode chip (micro LED chip or uLED chip) including the n-electrode, an n-type layer, an active layer, a p-type layer, and the p-electrode. The light-emitting element 160 may have a flip-chip structure in which the n-electrode and the p-electrode are provided on the same side (for example, a side facing the base substrate 110) and light is emitted through a side opposite to the side provided with the n-electrode and the p-electrode (for example, a side opposite to the side facing the base substrate 110).

However, embodiments of the present disclosure are not limited thereto. The light-emitting element 160 may have a lateral structure in which the n-electrode and the p-electrode are provided on the same side and light is emitted through the same side provided with the n-electrode and the p-electrode or may have a vertical structure in which the n-electrode and the p-electrode are provided on opposite sides, respectively.

The first element electrode 162 of the light-emitting element 160 may overlap the first electrode 142, and the second element electrode 164 of the light-emitting element 160 may overlap the second electrode 144. The first element electrode 162 may be electrically connected to the first electrode 142 through the conductive balls 152 of the adhesive layer 150, and the second element electrode 164 may be electrically connected to the second electrode 144 through the conductive balls 152 of the adhesive layer 150. Accordingly, the second element electrode 164 may be connected to the low potential voltage ELVSS through the second electrode 144.

Meanwhile, an auxiliary pattern 170 may be provided in the auxiliary soft portion A3. See FIG. 5. The auxiliary pattern 170 may be in contact with the first adhesive layer 104, such that the second base portion 110b is not included on the first adhesive layer 104. The auxiliary pattern 170 may be spaced apart from the rigid portion A1 and the soft portion A2. A side of the auxiliary pattern 170 is spaced from a side of the soft portion A2 by a distance.

A height of the auxiliary pattern 170 may be smaller than or equal to a height of the rigid portion A1 and may be equal to or greater than a height of the soft portion A2. In addition, a thickness of the auxiliary pattern 170 may be smaller than or equal to a thickness of the rigid portion A1 and may be equal to or greater than a thickness of the soft portion A2. At this time, the height and thickness may be based on the first adhesive layer 104 and may be the same. The height of the rigid portion A1 may correspond to the height of the components of the rigid portion A1 except for the light-emitting element 160 and the adhesive layer 150, such as from a top surface 173 of the stretchable line 146 in the rigid portion A1 to a surface of the first adhesive layer 104.

Specifically, the rigid portion A1 except for the light-emitting element 160 may have a first height h1, the soft portion A2 may have a second height h2, and the auxiliary pattern 170 may have a third height h3.

The first height h1 may correspond to a length or dimension from the bottom surface of the first base portion 110a, that is, the top surface of the first adhesive layer 104 to the top surface 173 of the stretchable line 146 in the rigid portion A1. The second height h2 may correspond to a length from the bottom surface of the second base portion 110b, that is, the top surface of the first adhesive layer 104 to the top surface of the stretchable line 146 in the soft portion A2. The third height h3 may correspond to a length from the bottom surface of the auxiliary pattern 170 to the top surface of the auxiliary pattern 170.

Here, the third height h3 may be equal to or greater than the second height h2 and smaller than or equal to the first height h1.

The auxiliary pattern 170 may be formed of at least one of an organic insulating material, an inorganic insulating material, and a metallic material. For example, the auxiliary pattern 170 may be formed of photosensitive acrylic polymer (photo acryl). However, embodiments of the present disclosure are not limited thereto.

The auxiliary pattern 170 may be formed through the same process as the planarization layer 118 of the rigid portion A1. In this case, the third height h3 of the auxiliary pattern 170 may be smaller than the first height h1 of the rigid portion A1.

Alternatively, the auxiliary pattern 170 may be formed through a different process from the planarization layer 118 of the rigid portion A1. For example, the auxiliary pattern 170 may include the base substrate 110, the first buffer layer 111, the second buffer layer 112, the gate insulation layer 113, the first interlayer insulation layer 114, the second interlayer insulation layer 115, the third interlayer insulation layer 116, the passivation layer 117, the first electrode 142, and the second electrode 144 or may include at least one of them.

Next, a dummy pattern 150a may be provided on the auxiliary pattern 170. The dummy pattern 150a may include the same material as the adhesive layer 150. That is, the dummy pattern 150a may be an anisotropic conductive film, and although not shown, the dummy pattern 150a may include a plurality of conductive balls therein. In FIG. 5, it is described that the dummy pattern 150a is provided on the auxiliary pattern 170. The dummy pattern is optional.

The dummy pattern 150a may include a first dummy pattern portion 150a1 and a second dummy pattern portion 150a2. The first dummy pattern portion 150a1 and the second dummy pattern portion 150a2 may be spaced apart from each other. Alternatively, the first dummy pattern portion 150a1 and the second dummy pattern portion 150a2 may be in contact with each other, and in this case, side surfaces of the first dummy pattern portion 150a1 and the second dummy pattern portion 150a2 may be in contact with each other.

The first dummy pattern portion 150a1 and the second dummy pattern portion 150a2 may be formed through different transfer processes. That is, the first dummy pattern portion 150a1 may be formed through the same transfer process as the adhesive layer 150 provided in the rigid portion A1 of FIG. 4, and the second dummy pattern portion 150a2 may be formed through the same transfer process as an adhesive layer provided in another rigid portion A1.

Meanwhile, the auxiliary pattern 170 may be the second pattern AP2 of FIG. 2, and the first pattern AP1 of FIG. 2 may have substantially the same cross-sectional structure as the auxiliary pattern 170. Accordingly, a dummy pattern may also be formed on the first pattern AP1.

Next, a second adhesive layer 108 may attach the light-emitting element 160, the stretchable line 146, and the dummy pattern 150a with the second substrate 106. The second adhesive layer 108 may be formed of the same material as the first adhesive layer 104. However, embodiments of the present disclosure are not limited thereto. In other embodiments, the second adhesive layer 108 may be formed of a different material from the first adhesive layer 104.

A thickness of the second adhesive layer 108 may be substantially the same as a thickness of the first adhesive layer 104.

As described above, in the stretchable display device according to the embodiment of the present disclosure, by providing the auxiliary pattern 170 in the auxiliary soft portion A3, the edge of the transfer film can be prevented from sagging when forming the adhesive layer 150.

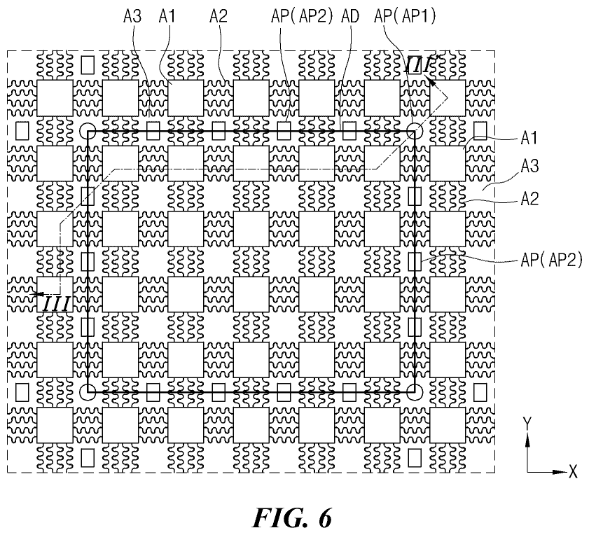

The prevention of edge sagging of the transfer film will be described with reference to FIGS. 6 to 8.

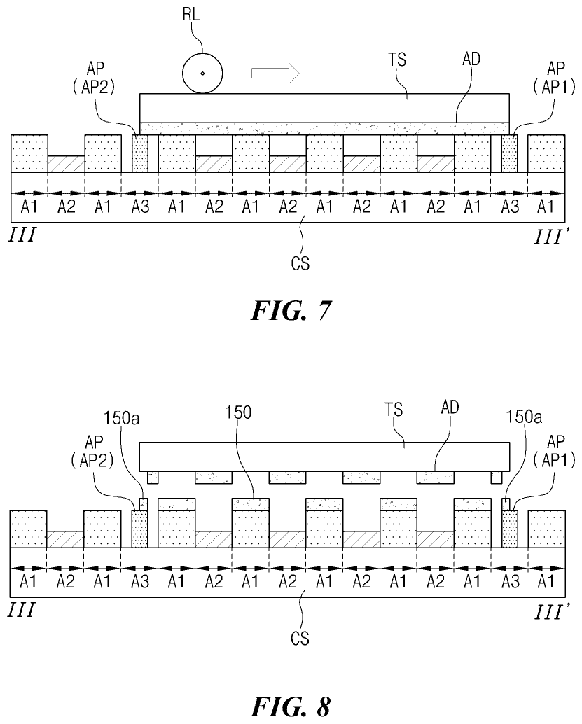

FIG. 6 is a schematic plan view of a stretchable display device according to the embodiment of the present disclosure in a transfer step of an adhesive layer. FIGS. 7 and 8 are schematic plan views of a stretchable display device according to the embodiment of the present disclosure in a transfer step of an adhesive layer and show cross-sections corresponding to line III-III′ of FIG. 6.

In FIGS. 6 to 8, the rigid portions A1, the soft portions A2, and the auxiliary soft portions A3 may be provided on a carrier substrate CS, and the auxiliary patterns AP may be selectively provided in the auxiliary soft portions A3. The auxiliary patterns AP may include the first pattern AP1 and the second pattern AP2.

The height of the auxiliary pattern AP may be smaller than or substantially equal to the height of the rigid portion A1 and may be equal to or greater than the height of the soft portion A2. In addition, the area of the auxiliary pattern AP may be equal to or greater than ¼ of the area of the corresponding auxiliary soft portion A3 and may be smaller than or equal to the area of the corresponding auxiliary soft portion A3.

A transfer film AD for the adhesive layer and a transfer substrate TS may be disposed over the rigid portion A1, the soft portion A2, and the auxiliary pattern AP. At this time, the auxiliary pattern AP may serve as an alignment key for aligning the transfer film AD.

The transfer film AD may be provided on the bottom surface of the transfer substrate TS. The transfer film AD may be in contact with the top surfaces of the rigid portion A1 and the auxiliary pattern AP and may be spaced apart from the soft portion A2.

The auxiliary pattern AP may be disposed to correspond to the size of the transfer film AD. Here, the auxiliary pattern AP may be disposed only in the auxiliary soft portion A3 corresponding to the edge of the transfer film AD and may not be disposed in other auxiliary soft portions A3. Accordingly, the edge of the transfer film AD may be disposed on the auxiliary pattern AP to be prevented from sagging downward due to the auxiliary pattern AP. At this time, to further prevent edge sagging of the transfer film, sagging may be improved by additionally forming the second pattern AP2 in another auxiliary soft portion adjacent to the auxiliary soft portion A3 in FIG. 7. In this case, the shape formed by the added second patterns AP2 may be a rectangular shape that has a smaller size than the rectangle formed by the auxiliary pattern AP shown in FIG. 7 corresponding to the transfer substrate TS.

Next, a roller RL may be provided on the top surface of the transfer substrate TS.

Then, after rotating the roller RL to press the transfer substrate TS while applying heat to the carrier substrate CS, as shown in FIG. 8, the transfer film AD and the transfer substrate TS may be detached, and the transfer film AD may be selectively transferred, thereby forming the adhesive layer 150 on the rigid portion A1. At this time, the dummy pattern 150a may be formed on the auxiliary pattern AP.

The detached transfer film AD may be reused to form the adhesive layer 150 on the rigid portions A1 in another area.

As described above, in the stretchable display device according to the embodiment of the present disclosure, by providing the auxiliary pattern AP in the auxiliary soft portion A3, the edge of the transfer film AD can be prevented from sagging when forming the adhesive layer 150, thereby preventing over-transfer of the anisotropic conductive film. Accordingly, it is possible to prevent the stability and quality deterioration of the stretchable display device due to the over-transfer. In addition, the manufacturing costs can be reduced by decreasing the amount of the anisotropic conductive film consumed due to the over-transfer.

The auxiliary pattern AP may be used as an alignment key. That is, as mentioned above, the auxiliary pattern AP may be used as an alignment key for aligning the carrier substrate CS and the transfer film AD to transfer the adhesive layer 150. Accordingly, since it is not needed to provide a separate alignment key, the manufacturing process can be simplified.

In addition, the auxiliary pattern AP may be used as an alignment key for transferring the light-emitting element 160 to the display panel. Generally, when the light-emitting element 160 is transferred to the display panel, an alignment key is needed to align positions of a donor provided with the light-emitting element 160 and the display panel provided with the rigid portion A1 such that the first and second elements electrodes 162 and 164 of the light-emitting element 160 may correspond to the first and second electrodes 142 and 144, respectively, and the align key may be provided outside the display area, that is, in the non-display area.

However, in the stretchable display device according to the embodiment of the present disclosure, by using the auxiliary pattern AP as the alignment key for transferring the light-emitting element 160, the alignment key in the non-display area may be omitted, and thus, the manufacturing costs may be further simplified.

Meanwhile, by preventing formation of the dummy pattern on the auxiliary pattern AP, the amount of the consumed anisotropic conductive film can be further reduced.

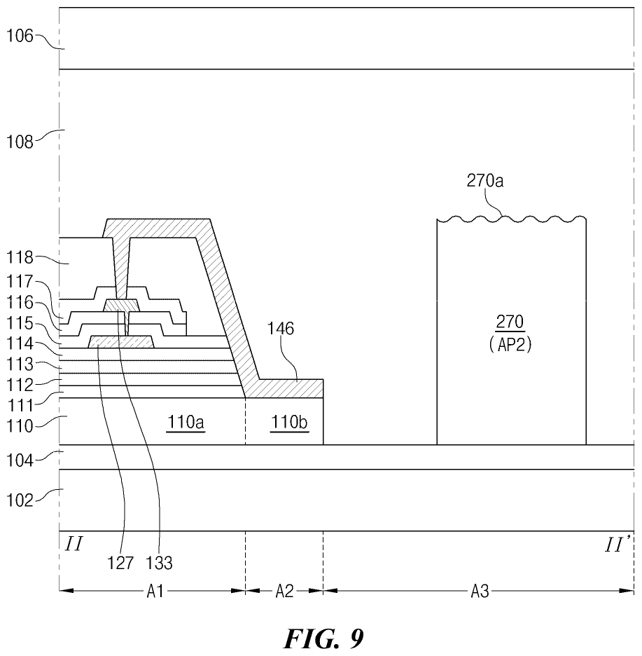

Such a stretchable display device according to another embodiment of the present disclosure will be described with reference to FIG. 9.

FIG. 9 is a schematic cross-sectional view of a stretchable display device according to another embodiment of the present disclosure and shows a cross-section corresponding to line II-II′ of FIG. 2. The stretchable display device according to another embodiment of the present disclosure has substantially the same configuration as that of the previous embodiment, except for the auxiliary pattern. The same parts as that of the previous embodiment are designated by the same reference signs, and explanation for the same parts may be shortened or omitted.

In FIG. 9, the auxiliary pattern 270 may be provided in the auxiliary soft portion A3. The auxiliary pattern 270 may be in contact with the first adhesive layer 104. The auxiliary pattern 270 may be spaced apart from the rigid portion A1 and the soft portion A2.

The height of the auxiliary pattern 270 may be smaller than or equal to the height of the rigid portion A1 and may be greater than the height of the soft portion A2. In addition, the thickness of the auxiliary pattern 270 may be smaller than or equal to the thickness of the rigid portion A1 and may be greater than the thickness of the soft portion A2.

The auxiliary pattern 270 may have a plurality of fine patterns 270a on its top surface. That is, the top surface of the auxiliary pattern 270 may not be flat or may be uneven, and unevenness may be provided at the top surface of the auxiliary pattern 270. Accordingly, the fine patterns 270a may include concave parts and convex parts.

The fine patterns 270a may minimize the contact area between the auxiliary pattern 270 and the transfer film AD in the transfer step of the adhesive layer, thereby preventing the dummy pattern from being formed on the auxiliary pattern 270.

Accordingly, in the stretchable display panel according to the another embodiment of the present disclosure, the amount of the consumed transfer film AD can be further reduced. Compared to the previous embodiment, the adhesive layer 150 can be formed over a larger area by performing a transfer process more times with one transfer film AD, so that the manufacturing costs can be reduced.

In the stretchable display panel of the present disclosure, the auxiliary pattern is provided in the auxiliary soft portion to prevent the over-transfer of the anisotropic conductive film. Accordingly, it is possible to prevent the stability deterioration of the stretchable display device and to reduce the manufacturing costs by decreasing the amount of the consumed anisotropic conductive film.

In addition, by providing the fine patterns at the top surface of the auxiliary pattern, the amount of the consumed anisotropic conductive film can be further reduced, and the manufacturing costs can be further decreased.

Further, by using the auxiliary pattern as the alignment key, the existing alignment key can be omitted, thereby further simplifying the manufacturing process.

Accordingly, the production energy can be reduced by optimizing the process.

The present disclosure includes a display that includes a plurality of rigid portions A1 that are adjacent to a plurality of soft portions A2. A plurality of supports AP are positioned between ones of the plurality of rigid portions and the plurality of soft portions. A number of the plurality of supports is smaller than a number of the plurality of rigid portions. The plurality of supports include a first shape and a second shape, a number of the first shape being greater than a number of the second shape. For example, see AP2's rectangular shape compared to AP1's round or circular shape. The plurality of supports are arranged in a rectangle with the second shape positioned at corners of the rectangle.

The present disclosure is directed to a display that includes a first rigid portion and a second rigid portion spaced from the first rigid portion along a first direction, such as the X direction in FIG. 2. A third rigid portion is spaced from the first rigid portion along a second direction transverse to the first direction. The second direction can be the Y direction in FIG. 2. There is a first soft portion A2 between the first and second rigid portions. There is a second soft portion between the first and third rigid portions. A first support AP2 is diagonally positioned between the second and third rigid portions. The display includes a fourth rigid portion spaced from the third rigid portion along the first direction. There is a second support AP1 that is spaced from the first and third rigid portions by the first support and the second and fourth rigid portions. The first support is a different shape than the second support.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A stretchable display device, comprising:
a plurality of rigid portions spaced apart from each other in a first direction and a second direction;
a plurality of soft portions each between adjacent ones of the plurality of rigid portions;
a plurality of auxiliary soft portions each between adjacent ones of the plurality of soft portions; and
a plurality of auxiliary patterns selectively provided in the plurality of auxiliary soft portions.

2. The stretchable display device of claim 1 wherein a height of a first one of the plurality of auxiliary patterns is equal to or greater than a height of the adjacent one of the plurality of soft portions and is smaller than or equal to a height of the adjacent one of the plurality of rigid portions.

3. The stretchable display device of claim 1, a group of the plurality of auxiliary patterns are arranged in a first rectangle.

4. The stretchable display device of claim 3, wherein the plurality of auxiliary patterns includes a first pattern and a second pattern, and
wherein the first pattern is at a vertex of the at least one rectangle, and the group is arranged in the second pattern as sides of the first rectangle.

5. The stretchable display device of claim 4, wherein the first pattern and the second pattern have different shapes.

6. The stretchable display device of claim 4, comprising a second rectangle having a smaller area than the first rectangle, the second rectangle includes.

7. The stretchable display device of claim 1, wherein a number of the plurality of auxiliary patterns is smaller than a number of the plurality of rigid portions.

8. The stretchable display device of claim 1, wherein an area of a first one of the plurality of auxiliary patterns is equal to or greater than ¼ of an area of the adjacent one of the plurality of soft portions.

9. The stretchable display device of claim 1, wherein ones of the plurality of auxiliary patterns include a plurality of concave and convex patterns on a top surface.

10. The stretchable display device of claim 1, further comprising a dummy pattern on the ones of the plurality of auxiliary patterns, wherein the dummy pattern is formed of a same material as an adhesive layer.

11. The stretchable display device of claim 10, wherein the dummy pattern includes a first dummy pattern portion and a second dummy pattern portion.

12. The stretchable display device of claim 11, wherein the first dummy pattern portion and the second dummy pattern portion are spaced apart from each other.

13. The stretchable display device of claim 12, wherein side surfaces of the first dummy pattern and the second dummy pattern are in contact with each other.

14. A device, comprising:
a display that includes:
a plurality of rigid portions;
a plurality of soft portions adjacent to the plurality of rigid portions;
a plurality of supports positioned between ones of the plurality of rigid portions and the plurality of soft portions, a number of the plurality of supports being smaller than a number of the plurality of rigid portions.

15. The device of claim 14 wherein the plurality of supports include a first shape and a second shape, a number of the first shape being greater than a number of the second shape.

16. The device of claim 15 wherein the plurality of supports are arranged in a rectangle with the second shape positioned at corners of the rectangle.

17. A device, comprising:
a display that includes:
a first rigid portion;
a second rigid portion spaced from the first rigid portion along a first direction;
a third rigid portion spaced from the first rigid portion along a second direction transverse to the first direction;
a first soft portion between the first and second rigid portions;
a second soft portion between the first and third rigid portions;
a first support diagonally positioned between the second and third rigid portions.

18. The device of claim 17 wherein the display includes:
a fourth rigid portion spaced from the third rigid portion along the first direction;
a second support spaced from the first and third rigid portions by the first support and the second and fourth rigid portions.

19. The device of claim 18 wherein the first support is a different shape than the second support.
